(19) United States
(12) Patent Application Publication
(10) Pub. No.: US 2024/0196618 A1
(43) Pub. Date: Jun. 13, 2024

(54) INTEGRATED CIRCUIT DEVICE AND ELECTRONIC SYSTEM INCLUDING THE SAME

(71) Applicant: Samsung Electronics Co., Ltd., Suwon-si (KR)

(72) Inventors: Byongju KIM, Suwon-si (KR); Dongsung CHOI, Suwon-si (KR); Wonjun PARK, Suwon-si (KR); Donghwa LEE, Suwon-si (KR); Jaemin JUNG, Suwon-si (KR); Changheon CHEON, Suwon-si (KR)

(21) Appl. No.: 18/528,970

(22) Filed: Dec. 5, 2023

(30) Foreign Application Priority Data
Dec. 7, 2022 (KR) 10-2022-0170049

(51) Int. Cl. H10B 43/27; H10B 41/27; H10B 51/20

(52) U.S. Cl. CPC H10B 43/27; H10B 41/27; H10B 51/20; G11C 16/14

(57) ABSTRACT

An integrated circuit device includes a semiconductor substrate; a plurality of conductive lines extending on the semiconductor substrate in a horizontal direction and overlapping each other in a vertical direction; a plurality of insulating layers between pairs of conductive lines of the plurality of conductive lines and extending in the horizontal direction; and a channel structure passing through the plurality of conductive lines and the plurality of insulating layers, wherein the channel structure includes a core insulating layer, a channel layer on a side wall and a bottom surface of the core insulating layer, a gate insulating layer on an outer wall of the channel layer, and a ferroelectric layer on an outer wall of the gate insulating layer.

### CROSS-REFERENCE TO RELATED APPLICATION

This application is based on and claims priority under 35 U.S.C. § 119 to Korean Patent Application No. 10-2022-0170049, filed on Dec. 7, 2022, in the Korean Intellectual Property Office, the disclosure of which is incorporated by reference herein in its entirety.

### BACKGROUND

### 1. Field

Embodiments relate to an integrated circuit device and an electronic system including the same.

### 2. Description of the Related Art

To satisfy excellent performance and economic feasibility, the integration of an integrated circuit device may be increased. In particular, the integration of a memory device may be factor in determining the economic feasibility of a product. The integration of a two-dimensional memory device may be mainly determined by an area occupied by a unit memory cell, and the integration of the two-dimensional memory device may be largely affected by the level of a fine pattern forming technique. However, pieces of expensive equipment may be to form a fine pattern, and the area of a chip die may be limited, and thus, the integration of two-dimensional memory devices has increased but may still be limited. Accordingly, there is a demand for vertical memory devices having a three-dimensional structure.

### SUMMARY

The embodiments may be realized by providing an integrated circuit device including a semiconductor substrate; a plurality of conductive lines extending on the semiconductor substrate in a horizontal direction and overlapping each other in a vertical direction; a plurality of insulating layers between pairs of conductive lines of the plurality of conductive lines and extending in the horizontal direction; and a channel structure passing through the plurality of conductive lines and the plurality of insulating layers, wherein the channel structure includes a core insulating layer, a channel layer on a side wall and a bottom surface of the core insulating layer, a gate insulating layer on an outer wall of the channel layer, and a ferroelectric layer on an outer wall of the gate insulating layer.

The embodiments may be realized by providing an integrated circuit device including a semiconductor substrate; a plurality of conductive lines extending on the semiconductor substrate in a horizontal direction and overlapping each other in a vertical direction; a plurality of insulating layers between pairs of conductive lines of the plurality of conductive lines and extending in the horizontal direction; and a channel structure passing through the plurality of conductive lines and the plurality of insulating layers, wherein the channel structure includes a core insulating layer, a channel layer on a side wall and a bottom surface of the core insulating layer, a gate insulating layer on an outer wall of the channel layer, and a high-k pattern and a ferroelectric pattern alternating in the vertical direction on an outer wall of the gate insulating layer.

The embodiments may be realized by providing an electronic system including a main substrate; an integrated circuit device on the main substrate; and a controller electrically connected to the integrated circuit device on the main substrate, wherein the integrated circuit device includes a semiconductor substrate; a plurality of conductive lines extending on the semiconductor substrate in a horizontal direction and overlapping each other in a vertical direction; a plurality of insulating layers between pairs of conductive lines of the plurality of conductive lines and extending in the horizontal direction; and a channel structure passing through the plurality of conductive lines and the plurality of insulating layers, and the channel structure includes a core insulating layer, a channel layer on a side wall and a bottom surface of the core insulating layer, a gate insulating layer on an outer wall of the channel layer, and a ferroelectric layer on at least a portion of an outer wall of the gate insulating layer.

### BRIEF DESCRIPTION OF THE DRAWINGS

Features will be apparent to those of skill in the art by describing in detail exemplary embodiments with reference to the attached drawings in which:

FIG. 1 is a block diagram illustrating an integrated circuit device according to an embodiment;

FIG. 2 is an equivalent circuit diagram of a memory cell array in an integrated circuit device, according to an embodiment;

FIG. 3 is a top view illustrating components of an integrated circuit device according to an embodiment;

FIG. 4 is a cross-sectional view taken along line IV-IV′ of FIG. 3;

FIG. 5 is a magnified view of part AA of FIG. 4;

FIG. 6 is a magnified view of part BB of FIG. 4;

FIG. 7 is a magnified view of part CC of FIG. 4;

FIGS. 8 and 9 are schematic diagrams illustrating energy band diagrams of an integrated circuit device according to an embodiment;

FIG. 10 is a cross-sectional view illustrating components of an integrated circuit device according to another embodiment;

FIG. 11 is a magnified view of part DD of FIG. 10;

FIGS. 12 to 16 are cross-sectional views of integrated circuit devices according to other embodiments;

FIG. 17 is a block diagram of an electronic system including an integrated circuit device, according to an embodiment; and

FIG. 18 is a perspective view of an electronic system including an integrated circuit device, according to an embodiment.

### DETAILED DESCRIPTION

Hereinafter, embodiments are described in detail with reference to the accompanying drawings.

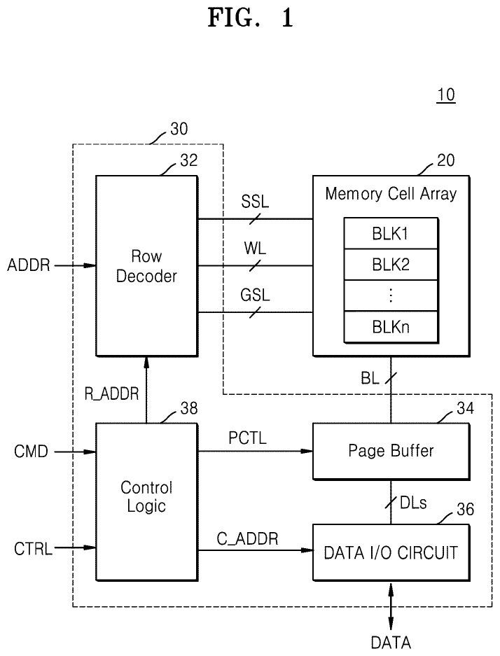

FIG. 1 is a block diagram illustrating an integrated circuit device 10 according to an embodiment.

Referring to FIG. 1, the integrated circuit device 10 may include a memory cell array 20 and a peripheral circuit 30.

The memory cell array 20 may include a plurality of memory cell blocks BLK1, BLK2, . . . , and BLKn. Each of the plurality of memory cell blocks BLK1, BLK2, . . . , and BLKn may include a plurality of memory cells. The plurality of memory cell blocks BLK1, BLK2, . . . , and BLKn may be connected to the peripheral circuit 30 through bit lines BL, word lines WL, string select lines SSL, and ground select lines GSL.

The memory cell array 20 may be connected to a page buffer 34 through the bit lines BL and connected to a row decoder 32 through the word lines WL, the string select lines SSL, and the ground select lines GSL. In the memory cell array 20, each of a plurality of memory cells included in each of the plurality of memory cell blocks BLK1, BLK2, . . . , and BLKn may be a flash memory cell. The memory cell array 20 may include a three-dimensional memory cell array. The three-dimensional memory cell array may include a plurality of NAND strings, and each of the plurality of NAND strings may include a plurality of memory cells vertically stacked and connected to a plurality of word lines WL.

The peripheral circuit 30 may include the row decoder 32, the page buffer 34, a data input-output circuit 36, and a control logic 38. In an implementation, the peripheral circuit 30 may further include various circuits, such as a voltage generation circuit configured to generate various voltages required for an operation of the integrated circuit device 10, an error correction circuit configured to correct an error of data read from the memory cell array 20, or an input-output interface.

The peripheral circuit 30 may receive an address ADDR, a command CMD, and a control signal CTRL from the outside of the integrated circuit device 10 and transmit and receive data DATA to and from a device outside the integrated circuit device 10.

A structure of the peripheral circuit 30 is particularly described below.

The row decoder 32 may select at least one of the plurality of memory cell blocks BLK1, BLK2, . . . , and BLKn in response to the address ADDR from the outside and may select a word line WL, a string select line SSL, and a ground select line GSL of the selected memory cell block. The row decoder 32 may provide, to the word line WL of the selected memory cell block, a voltage for performing a memory operation.

The page buffer 34 may be connected to the memory cell array 20 through the bit lines BL. The page buffer 34 may operate as a write driver during a program operation to apply, to the bit lines BL, a voltage according to the data DATA to be stored in the memory cell array 20, and may operate as a sensing amplifier during a read operation to sense the data DATA stored in the memory cell array 20. The page buffer 34 may operate in response to a control signal PCTL provided from the control logic 38.

The data input-output circuit 36 may be connected to the page buffer 34 through data lines DLs. During a program operation, the data input-output circuit 36 may receive the data DATA from a memory controller and provide the data DATA to the page buffer 34 as program data based on a column address C_ADDR provided from the control logic 38. During a read operation, the data input-output circuit 36 may provide the data DATA stored in the page buffer 34 to the memory controller as read data based on the column address C_ADDR provided from the control logic 38. The data input-output circuit 36 may provide an input address or instruction to the control logic 38 or the row decoder 32.

The control logic 38 may receive the command CMD and the control signal CTRL from the memory controller. The control logic 38 may provide a row address R ADDR to the row decoder 32 and provide the column address C_ADDR to the data input-output circuit 36. The control logic 38 may generate various kinds of internal control signals to be used inside the integrated circuit device 10, in response to the control signal CTRL. In an implementation, the control logic 38 may adjust voltage levels to be provided to the word lines WL and the bit lines BL during a memory operation, such as a program operation or an erase operation.

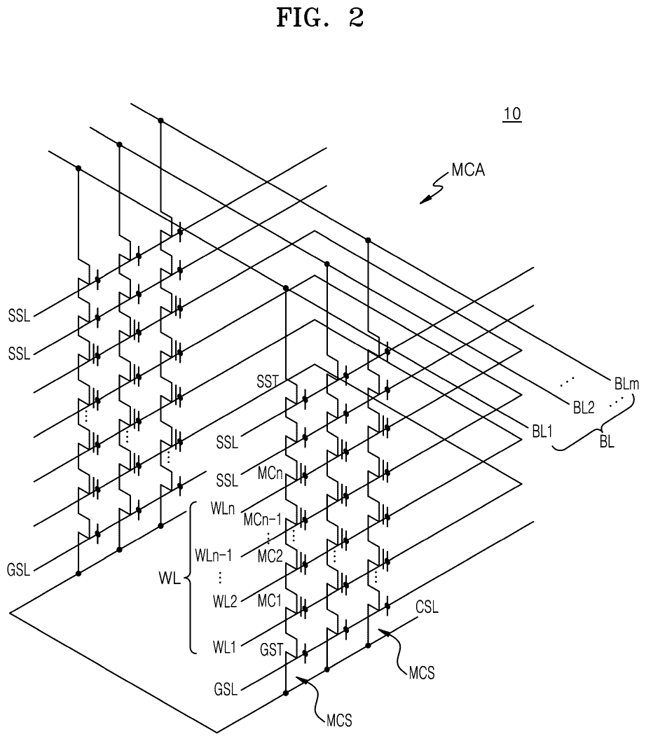

FIG. 2 is an equivalent circuit diagram of a memory cell array MCA in the integrated circuit device 10, according to an embodiment.

Referring to FIG. 2, an equivalent circuit diagram of a vertical NAND flash memory device having a vertical channel structure is illustrated.

In the integrated circuit device 10 according to an embodiment, the memory cell array MCA may include a plurality of memory cell strings MCS. The memory cell array MCA may include a plurality of bit lines BL, a plurality of word lines WL, at least one string select line SSL, at least one ground select line GSL, and a common source line CSL.

The plurality of memory cell strings MCS may be between the plurality of bit lines BL and the common source line CSL. In an implementation, each of the plurality of memory cell strings MCS may include two string select lines SSL. In an implementation, each of the plurality of memory cell strings MCS may include one string select line SSL.

Each of the plurality of memory cell strings MCS may include a string select transistor SST, a ground select transistor GST, and a plurality of memory cell transistors MC1, MC2, . . . , MCn−1, and MCn. A drain region of the string select transistor SST may be connected to a bit line BL, and a source region of the ground select transistor GST may be connected to the common source line CSL. The common source line CSL may be a region to which source regions of a plurality of ground select transistors GST are commonly connected.

The string select transistor SST may be connected to a string select line SSL, and the ground select transistor GST may be connected to a ground select line GSL. The plurality of memory cell transistors MC1, MC2, . . . , MCn−1, and MCn may be connected to the plurality of word lines WL, respectively.

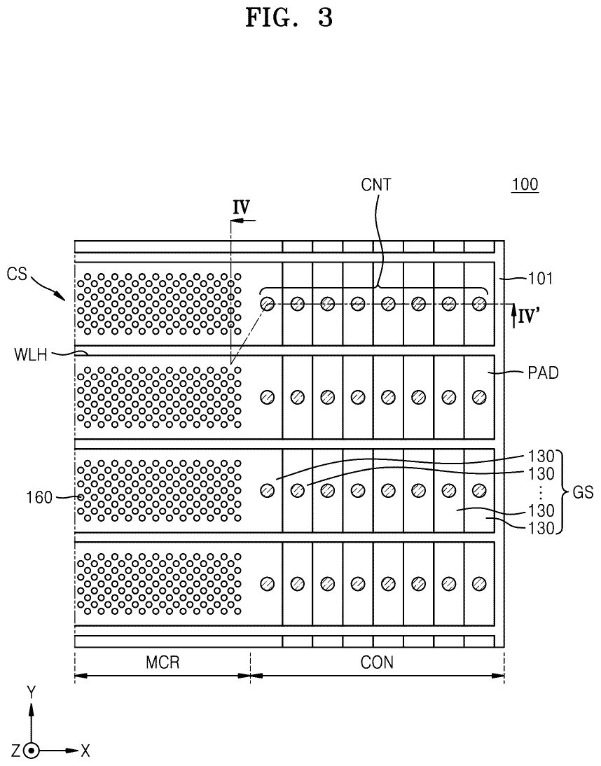

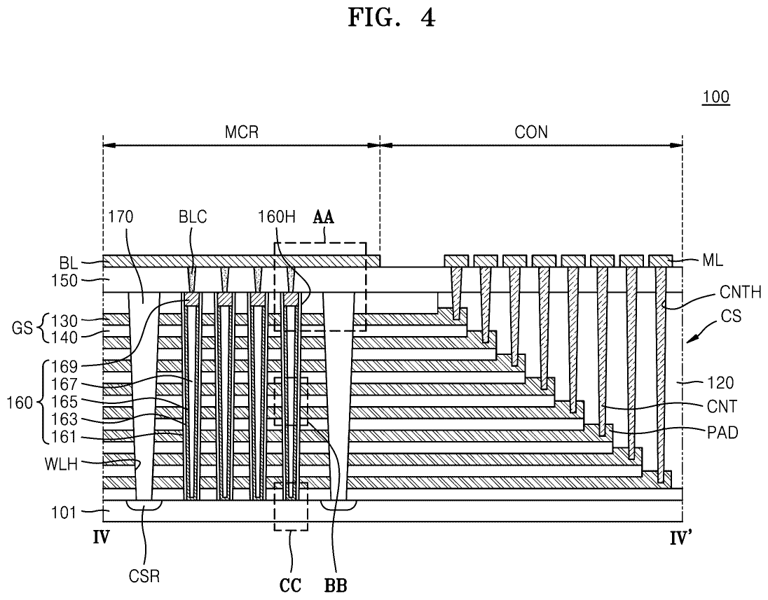

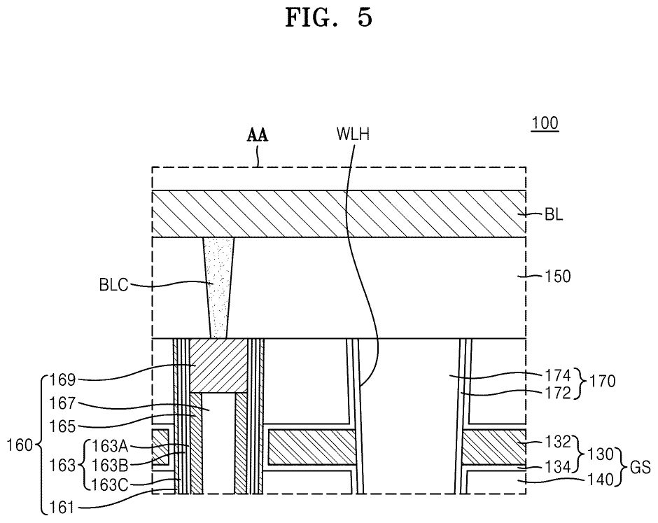

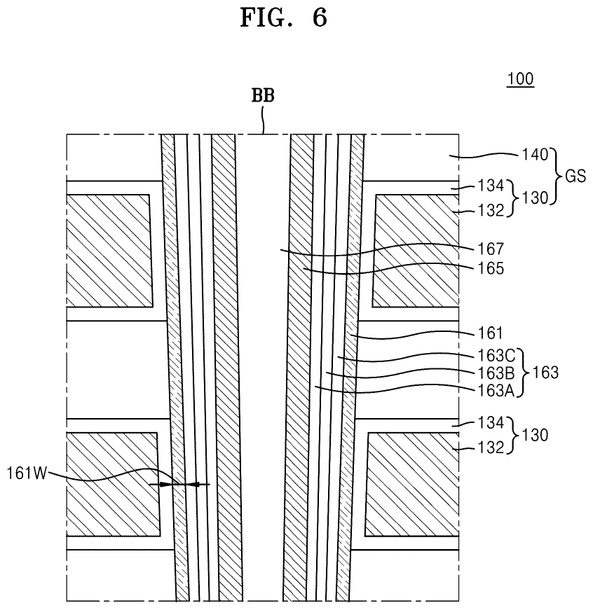

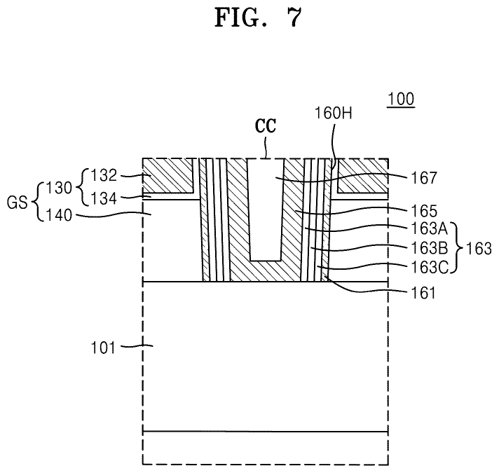

FIG. 3 is a top view illustrating components of an integrated circuit device 100 according to an embodiment, FIG. 4 is a cross-sectional view taken along line IV-IV′ of FIG. 3, FIG. 5 is a magnified view of part AA of FIG. 4, FIG. 6 is a magnified view of part BB of FIG. 4, and FIG. 7 is a magnified view of part CC of FIG. 4.

Referring to FIGS. 3 to 7, the integrated circuit device 100 may include a memory cell region MCR and a connection region CON.

The memory cell region MCR may be a region in or on which the NAND-type memory cell array MCA having a vertical channel structure, which has been described above with reference to FIG. 2, may be formed. The connection region CON may be a region in or on which a pad portion PAD electrically connecting a peripheral circuit region to the memory cell array MCA formed in the memory cell region MCR may be formed.

A semiconductor substrate 101 may include a semiconductor material, e.g., a Group IV semiconductor, a Group III-V compound semiconductor, or a Group II-VI oxide semiconductor. In an implementation, the Group IV semiconductor may include silicon (Si), germanium (Ge), or SiGe. The semiconductor substrate 101 may be provided as a bulk wafer or a wafer having an epitaxial layer formed therein. In an implementation, the semiconductor substrate 101 may include a silicon-on-insulator (SOI) substrate or a germanium-on-insulator (GeOI) substrate. As used herein, the term “or” is not an exclusive term, e.g., “A or B” would include A, B, or A and B.

A gate stack GS may extend on the semiconductor substrate 101 in a first direction (an X direction) and a second direction (a Y direction), which are parallel to a main surface of the semiconductor substrate 101. The gate stack GS may include a plurality of gate electrodes 130 and a plurality of first insulating layers 140, and the plurality of gate electrodes 130 and the plurality of first insulating layers 140 may be alternately disposed in a third direction (a vertical or Z direction) that is perpendicular to an upper surface of the semiconductor substrate 101. In an implementation, an upper insulating layer 150 may be on the gate stack GS in the highest layer.

The gate electrode 130 may include a buried conductive layer 132 and an insulating liner 134 surrounding an upper surface, a lower surface, and a side surface of the buried conductive layer 132. In an implementation, the buried conductive layer 132 may include a metal, such as tungsten (W), metal silicide, such as tungsten silicide, doped polysilicon, or a combination thereof. In an implementation, the insulating liner 134 may include a metal oxide layer and include, e.g., a high-k material, such as aluminum oxide (Al₂O₃).

The plurality of gate electrodes 130 may correspond to the ground select line GSL, the word lines WL, and the at least one string select line SSL constituting the memory cell string MCS described above with reference to FIG. 2. In an implementation, the gate electrode 130 in the lowest layer may function as the ground select line GSL, the gate electrode 130 in the highest layer may function as the string select line SSL, and the other gate electrodes 130 may function as the word lines WL. Accordingly, the memory cell string MCS, in which the ground select transistor GST, the string select transistor SST, and the plurality of memory cell transistors MC1, MC2, . . . , MCn−1, and MCn between the ground select transistor GST and the string select transistor SST are connected in series, may be provided.

A plurality of word line cuts 170 may extend (e.g., lengthwise) on the semiconductor substrate 101 in the first direction (the X direction). The gate stack GS between a pair of word line cuts 170 may constitute one block, and the pair of word line cuts 170 may limit a width of the gate stack GS in the second direction (the Y direction). The word line cut 170 may include an insulating spacer 172 and an insulating isolation layer 174. In an implementation, the word line cut 170 may include an insulating structure. A plurality of common source regions CSR may be in the semiconductor substrate 101. The plurality of common source regions CSR may be an impurity region doped with a high concentration of impurities.

A plurality of channel structures 160 may extend in the third direction (the Z direction) by passing through the gate stack GS from the upper surface of the semiconductor substrate 101 in the memory cell region MCR. The plurality of channel structures 160 may be spaced apart by a predetermined distance from each other in the first direction (the X direction) and the second direction (the Y direction). The plurality of channel structures 160 may be arranged in a zigzag shape or a staggered shape.

Each of the plurality of channel structures 160 may extend inside a channel hole 160H passing through the gate stack GS. Each of the plurality of channel structures 160 may include a ferroelectric layer 161, a gate insulating layer 163, a channel layer 165, a core insulating layer 167, and a conductive plug 169. The ferroelectric layer 161, the gate insulating layer 163, and the channel layer 165 may be sequentially on a side wall of the channel hole 160H. In an implementation, the ferroelectric layer 161 may be conformally on the side wall of the channel hole 160H, the gate insulating layer 163 may be conformally on the ferroelectric layer 161, and the channel layer 165 may be conformally on the gate insulating layer 163 and a bottom portion of the channel hole 160H. The core insulating layer 167 filling a remaining space of the channel hole 160H may be on the channel layer 165. The conductive plug 169 may cover an entrance (e.g., the top) of the channel hole 160H, may be in contact (e.g., direct contact) with the channel layer 165, and may be at an upper side of the channel hole 160H. In an implementation, the core insulating layer 167 may be omitted, and the channel layer 165 may have a pillar shape filling a remaining portion of the channel hole 160H.

The plurality of channel structures 160 may be in contact with the semiconductor substrate 101. In an implementation, the channel layer 165 may be in contact with the upper surface of the semiconductor substrate 101 at the bottom portion of the channel hole 160H. In an implementation, a contact semiconductor layer having a certain height may be on the semiconductor substrate 101 at the bottom portion of the channel hole 160H, and the channel layer 165 may be electrically connected to the semiconductor substrate 101 via the contact semiconductor layer.

The ferroelectric layer 161 may be along the side wall of the channel hole 160H. The ferroelectric layer 161 may include, e.g., hafnium zirconium oxide (HfZrO). In an implementation, the HfZrO may include hafnium (Hf) and zirconium (Zr) at a ratio of, e.g., about 1:1. In an implementation, a width 161 W of the ferroelectric layer 161 in the horizontal direction (the X or Y direction) may be, e.g., about 30 Å to about 100 Å.

The ferroelectric layer 161 may be in contact with the insulating liner 134. In an implementation, the insulating liner 134 (including a metal oxide layer) may be between each of a plurality of buried conductive layers 132 and the ferroelectric layer 161. In an implementation, due to remanent polarization of the ferroelectric layer 161, movement of electrons or holes stored in a charge storage layer 163B may be suppressed. A detailed description of the remanent polarization of the ferroelectric layer 161 is made below.

The gate insulating layer 163 may be on a (e.g., inner) side wall of the ferroelectric layer 161. The gate insulating layer 163 may have a structure sequentially including a tunneling dielectric layer 163A, the charge storage layer 163B, and a blocking dielectric layer 163C (e.g., layered from the outer side of the channel layer 165 to the inner side of the ferroelectric layer 161). In an implementation, relative thicknesses of the tunneling dielectric layer 163A, the charge storage layer 163B, and the blocking dielectric layer 163C of the gate insulating layer 163 may be variously modified. The blocking dielectric layer 163C may be in contact with the ferroelectric layer 161. In an implementation, the ferroelectric layer 161 may be included in the blocking dielectric layer 163C.

The tunneling dielectric layer 163A may include, e.g., silicon oxide, hafnium oxide (HfO), Al₂O₃, zirconium oxide, tantalum oxide, or the like. The charge storage layer 163B may be a region in which electrons having passed through the tunneling dielectric layer 163A from the channel layer 165 may be stored, and may include, e.g., silicon nitride, boron nitride, silicon boron nitride, or impurity-doped polysilicon. The blocking dielectric layer 163C may include, e.g., silicon oxide, silicon nitride, or metal oxide having a greater dielectric constant than the silicon oxide. In an implementation, a thickness of the blocking dielectric layer 163C in the horizontal direction (the X or Y direction) may be, e.g., about 20 Å to about 50 Å.

The gate electrode 130 in the highest layer in one block may be divided into two portions by a string separation insulating layer in a top view. The two portions may form the string select lines SSL described above with reference to FIG. 2.

In the connection region CON, the gate electrode 130 may extend to form the pad portion PAD at an end portion of the gate electrode 130, and a cover insulating layer 120 may cover the pad portion PAD. In the connection region CON, the plurality of gate electrodes 130 may extend to have a length gradually decreasing in the first direction (the X direction) away in the third direction (the Z direction) from the upper surface of the semiconductor substrate 101. In an implementation, in the connection region CON, the plurality of gate electrodes 130 may have a stair structure.

In the connection region CON, a contact plug CNT may be connected to the pad portion PAD of the gate electrode 130 by passing through the cover insulating layer 120. The contact plug CNT may have a tapered pillar shape of which a width gradually decreases in the third direction (the Z direction) from an upper region to a lower region.

A bit line contact BLC may be in contact with the conductive plug 169 of a channel structure 160 by passing through the upper insulating layer 150, and a bit line BL may be in contact with the bit line contact BLC and may extend on the upper insulating layer 150 in the second direction (the Y direction). In an implementation, in the connection region CON, a conductive line ML may be on the upper insulating layer 150. In an implementation, an upper support layer may be further included between the upper insulating layer 150 and the bit line BL and between the upper insulating layer 150 and the conductive line ML.

In a vertical flash memory device, the gate insulating layer 163 for charge trap flash (CTF) may include the tunneling dielectric layer 163A, the charge storage layer 163B, and the blocking dielectric layer 163C. A CTF operation is a manner of storing electrons or holes in the charge storage layer 163B through Fowler-Nordheim (F-N) tunneling by applying a (+) or (−) voltage to a gate electrode. In this manner, information may be stored by changing a threshold voltage Vth, and the information may be obtained by reading the threshold voltage Vth. Characteristics that a low working voltage is necessary when storing electrons or holes in the charge storage layer 163B, and stored charges are continuously maintained in the charge storage layer 163B even in a state in which an external bias is removed, may be requirements of a flash memory device.

To lower the working voltage, a larger field may be applied to the tunneling dielectric layer 163A even in the same external bias state. To make this environment, as a capacitance of the blocking dielectric layer 163C increases, a voltage of the tunneling dielectric layer 163A may increase by a coupling ratio. In addition, to help prevent movement of electrons or holes stored through F-N tunneling to the gate electrode 130, a material having a high band gap may be added to the charge storage layer 163B to increase a barrier height. In an implementation, arranging the blocking dielectric layer 163C to be in contact with the charge storage layer 163B may increase the barrier height. However, to increase a field of the tunneling dielectric layer 163A, the capacitance of the blocking dielectric layer 163C is supposed to be high, but a dielectric constant of silicon oxide forming the blocking dielectric layer 163C may be relatively low, and thus, a coupling ratio may decrease.

In addition, if trapping and de-trapping of electrons or holes were to occur, a loss of information could occur. To prevent the de-trapping, charges may be prevented from moving to the outside of the charge storage layer 163B. If electrons or holes exist in the charge storage layer 163B, a potential may increase due to a Coulomb force, thereby increasing a driving force for the electrons or the holes to move to the outside. Therefore, a retention characteristic that stored charges are continuously maintained even in a state in which an external bias is removed is demanded, and the retention characteristic is associated with the reliability of a flash memory device.

The integrated circuit device 100 according to according to an embodiment may help prevent a loss of charges even while decreasing a working voltage. In an implementation, by substituting the ferroelectric layer 161 for a portion of the blocking dielectric layer 163C, movement of electrons or holes to the outside by the Coulomb force may be prevented due to remanent polarization generated in the ferroelectric layer 161 even while decreasing a working voltage by a high-k characteristic.

Eventually, in the integrated circuit device 100 according to an embodiment, by arranging the ferroelectric layer 161 outside the gate insulating layer 163 in the channel structure 160 and using the remanent polarization of the ferroelectric layer 161 to prevent a loss of electrons or holes, the retention characteristic and product reliability may be improved.

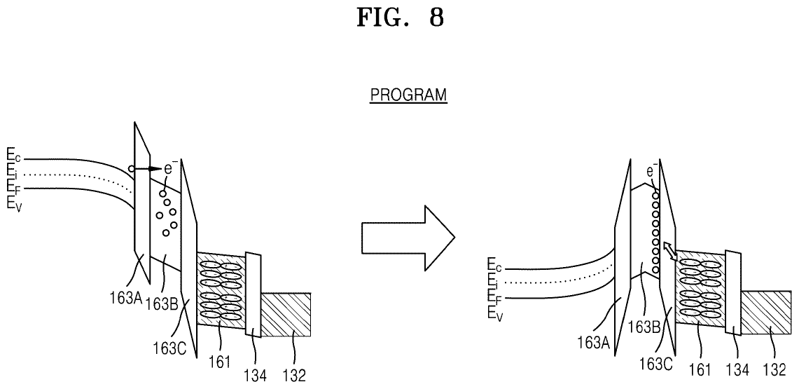

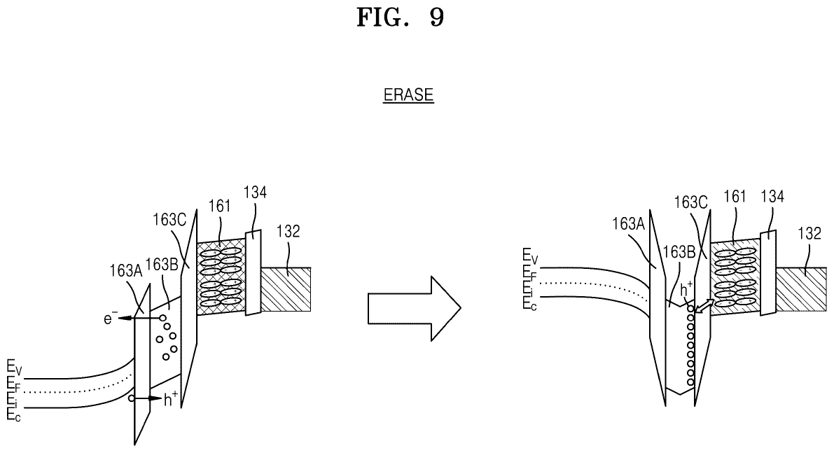

FIGS. 8 and 9 are schematic diagrams illustrating energy band diagrams of an integrated circuit device according to an embodiment.

Referring to FIGS. 8 and 9, energy band diagrams of an integrated circuit device according to a program operation and an erase operation are respectively shown.

The capacitance of the blocking dielectric layer 163C may be increased by inserting the ferroelectric layer 161 (having a relatively large band gap energy and dielectric constant) between the blocking dielectric layer 163C and the insulating liner 134.

As the capacitance of the blocking dielectric layer 163C increases, a coupling ratio may increase, thereby relatively decreasing an external bias for causing the same field to the charge storage layer 163B. In addition, remanent polarization of the ferroelectric layer 161, which may occur in this process, may be maintained even when an external bias is removed, and movement of stored electrons or holes to the outside of the charge storage layer 163B may be prevented by the remanent polarization.

As shown in FIGS. 8 and 9, the remanent polarization of the ferroelectric layer 161 may have opposite polarities according to the program operation (see FIG. 8) and the erase operation (see FIG. 9), and charges of the opposite polarities may be trapped at a position close to the charge storage layer 163B. In addition, attraction may be applied by a Coulomb force according to the remanent polarization to decrease a probability that the charges are de-trapped. Accordingly, during the program operation and the erase operation, the charges stored in the charge storage layer 163B may be stably maintained, and there is no substantial change in the threshold voltage Vth, and thus, product reliability may be improved.

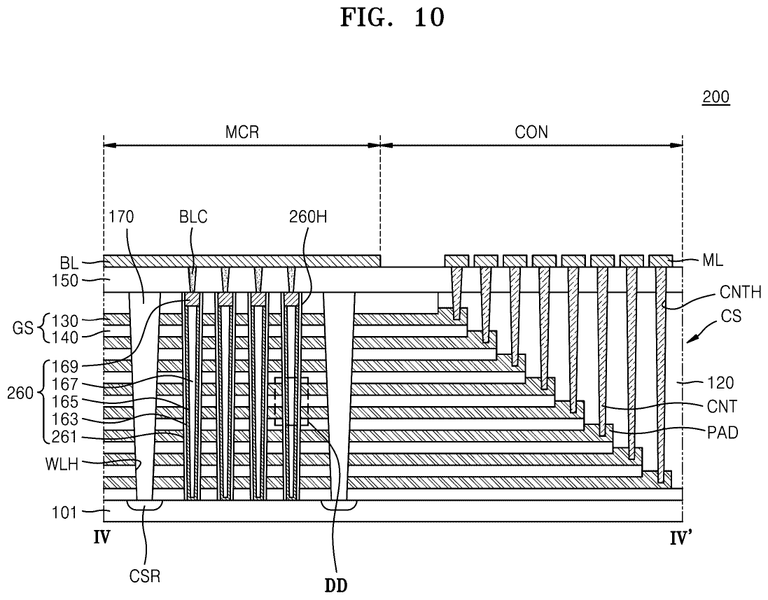

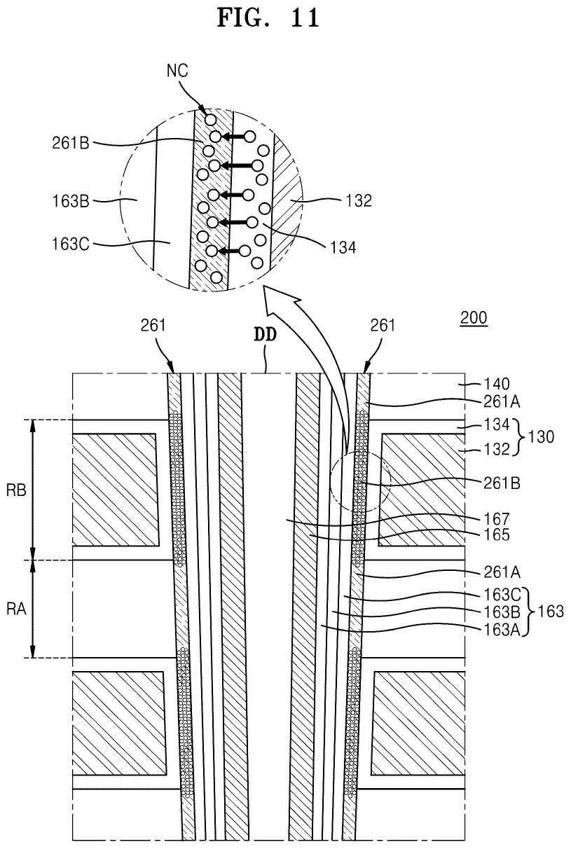

FIG. 10 is a cross-sectional view illustrating components of an integrated circuit device 200 according to another embodiment, and FIG. 11 is a magnified view of part DD of FIG. 10.

For convenience of description, FIG. 10 corresponds with a cross-sectional view taken along line IV-IV′ of FIG. 3.

Hereinafter, most components constituting the integrated circuit device 200 and materials forming the components may be substantially the same as or similar to those described above with reference to FIGS. 3 to 9. Therefore, for convenience of description, differences from the integrated circuit device 100 described above may be mainly described.

Referring to FIGS. 10 and 11, the integrated circuit device 200 may include a dielectric pattern layer 261 including a high-k pattern 261A and a ferroelectric pattern 261B alternately on an outer wall of the gate insulating layer 163 in the third direction (the Z direction).

In an embodiment, each of a plurality of channel structures 260 may extend inside a channel hole 260H passing through the gate stack GS, and the dielectric pattern layer 261 may be on a side wall of the channel hole 260H. The dielectric pattern layer 261 may alternately include the high-k pattern 261A and the ferroelectric pattern 261B. In an implementation, the high-k pattern 261A may include HfO, and the ferroelectric pattern 261B may include hafnium aluminum oxide (HfAlO). In the dielectric pattern layer 261, aluminum (Al) included in the ferroelectric pattern 261B may exist by spreading from the insulating liner 134.

The insulating liner 134 may include a metal oxide layer, e.g., a high-k material, such as Al₂O₃. In an implementation, Al atoms included in the insulating liner 134 may move to the dielectric pattern layer 261 in an insulating liner crystallization process (e.g., a spike annealing process) and form nanocrystals NC in the ferroelectric pattern 261B. Herein, the nanocrystals NC may indicate spherical particles of which a mean diameter is nanometers (nm). In an implementation, the ferroelectric pattern 261B may be in contact with the insulating liner 134. In an implementation, Al₂O₃ may be between each of the plurality of buried conductive layers 132 and the ferroelectric pattern 261B. In an implementation, remanent polarization of the ferroelectric pattern 261B may help suppress movement of electrons or holes stored in the charge storage layer 163B. The effect of the remanent polarization may be the same as described above.

The gate insulating layer 163 may be on a side wall of the dielectric pattern layer 261. The gate insulating layer 163 may have a structure sequentially including the tunneling dielectric layer 163A, the charge storage layer 163B, and the blocking dielectric layer 163C. In an implementation, relative thicknesses of the tunneling dielectric layer 163A, the charge storage layer 163B, and the blocking dielectric layer 163C forming the gate insulating layer 163 may be variously modified.

The integrated circuit device 200 according to an embodiment may provide a structure by which product reliability may be improved while minimizing a change in a manufacturing process. A method of manufacturing the integrated circuit device 200 is described below.

HfO may first be formed inside the channel hole 260H, and then the remaining channel structure 260 may be sequentially formed. In an implementation, a sacrificial mold layer between first insulating layers 140 may be removed, and then the insulating liner 134 may be conformally formed in a region from which the sacrificial mold layer has been removed. The insulating liner 134 may include Al₂O₃, and a spike annealing process may be performed at a temperature of about 1,000° C. or higher to crystallize Al₂O₃. By the spike annealing process, some Al atoms of the Al₂O₃ may move to adjacent HfO.

If a small amount of Al is added to HfO as an impurity, nanocrystals NC of a HfAlO composition having a ferroelectric characteristic may be formed. In an implementation, the nanocrystals NC may not be formed in pure HfO but formed only in HfAlO by the spike annealing process.

Therefore, nanocrystals NC may not be formed in a first region RA (a region in which the dielectric pattern layer 261 is in contact with the first insulating layer 140) because it may be difficult for the Al atoms to spread, and nanocrystals NC may be formed in a second region RB (a region in which the dielectric pattern layer 261 is in contact with the insulating liner 134) by diffusion of Al atoms. In an implementation, the first region RA may include HfO.

In an implementation, in the first region RA, a vertical length of the first insulating layer 140 in the third direction (the Z direction) may be slightly greater than or equal to a vertical length of a facing high-k pattern 261A in the third direction (the Z direction). This may be because a tiny amount of nanocrystals NC may spread to the high-k pattern 261A facing the first insulating layer 140.

If a (+) voltage is applied to the gate electrode 130, an energy band may be curved by a field, and electrons in the channel layer 165 move to the charge storage layer 163B through F-N tunneling so that a program operation is performed. On the contrary, if a (−) voltage is applied to the gate electrode 130, holes in the channel layer 165 may move to the charge storage layer 163B through F-N tunneling so that an erase operation is performed. During a program operation and an erase operation, there may be no problem in terms of energy even when electrons or holes exist in the charge storage layer 163B by applying a voltage to the gate electrode 130. However, if no voltage were to be applied to the gate electrode 130 (i.e., in a floating state), a potential could be formed by electrons or holes existing in the charge storage layer 163B, and it could be unstable in terms of energy. This characteristic may be analyzed because of a Coulomb force acting among electrons or holes.

As described above, if electrons or holes exist in the charge storage layer 163B, a potential may increase due to a Coulomb force, thereby increasing a driving force for the electrons or the holes to move to the outside. Therefore, a retention characteristic that stored charges are continuously maintained even in a state in which an external bias is removed may be demanded, and the retention characteristic may be associated with the reliability of a flash memory device.

The nanocrystals NC forming the ferroelectric pattern 261B may have a ferroelectric characteristic, and remanent polarization may occur during a program operation and an erase operation. The remanent polarization may be maintained in the nanocrystals NC even when an external bias is removed. As described above, the remanent polarization may help prevent movement of electrons or holes to the outside and contribute to improvement of product reliability.

As the size of the integrated circuit device 200 decreases, it may be good in terms of product reliability to help suppress movement of electrons or holes in the horizontal direction (the X or Y direction). In addition, the method of manufacturing the integrated circuit device 200 according to an embodiment may change a portion of a high-k layer to a ferroelectric layer based on movement of Al atoms, and high productivity and product reliability may be expected using nanocrystals NC forming HfAlO.

Eventually, in the integrated circuit device 200 according to an embodiment, by arranging the dielectric pattern layer 261 outside the gate insulating layer 163 in the channel structure 260 and using the remanent polarization of the ferroelectric pattern 261B included in the dielectric pattern layer 261 to help prevent a loss of electrons or holes, the retention characteristic and product reliability may be improved.

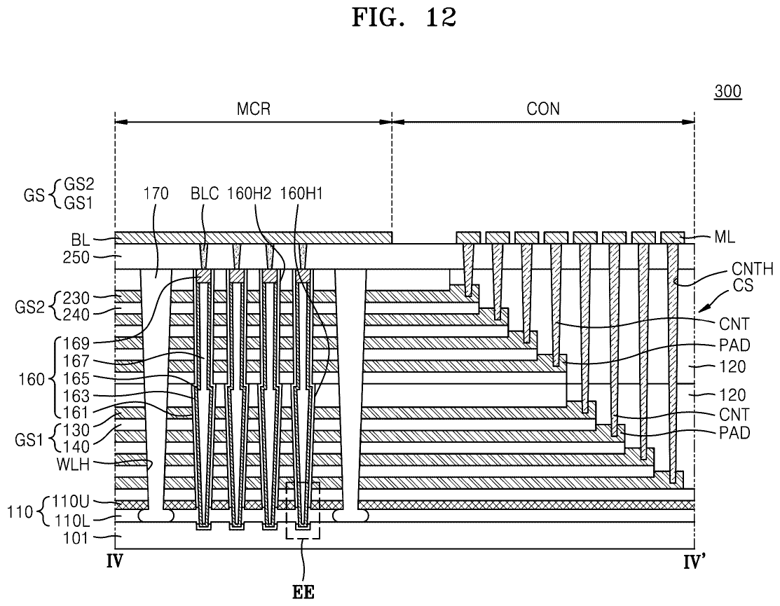

FIGS. 12 to 16 are cross-sectional views of integrated circuit devices 300, 400, and 500 according to other embodiments.

Hereinafter, most components constituting the integrated circuit devices 300, 400, and 500 and materials forming the components are substantially the same as or similar to those described above with reference to FIGS. 3 to 11. Therefore, for convenience of description, differences from the integrated circuit devices 100 and 200 described above may be mainly described.

Referring to FIGS. 12 to 14, the integrated circuit device 300 may include a first gate stack GS1 at a lower portion thereof and a second gate stack GS2 at an upper portion thereof.

In the integrated circuit device 300 according to the present embodiment, the first gate stack GS1 may include a plurality of first gate electrodes 130 and a plurality of first insulating layers 140, and the plurality of first gate electrodes 130 and the plurality of first insulating layers 140 may be alternately disposed in the third direction (the Z direction) that is perpendicular to an upper surface of a base structure 110.

The second gate stack GS2 may include a plurality of second gate electrodes 230 and a plurality of second insulating layers 240, and the plurality of second gate electrodes 230 and the plurality of second insulating layers 240 may be alternately disposed above the first gate stack GS1 in the third direction (the Z direction). In addition, a second upper insulating layer 250 may be on the second gate stack GS2 in the highest layer. In addition, in the connection region CON, the first gate stack GS1 may have a first stair structure, and the second gate stack GS2 may have a second stair structure.

Each of the plurality of channel structures 160 may extend inside a first channel hole 160H1 passing through the first gate stack GS1 and a second channel hole 160H2 passing through the second gate stack GS2. Each of the plurality of channel structures 160 may have a shape protruding outwardly at a boundary portion of the first channel hole 160H1 and the second channel hole 160H2.

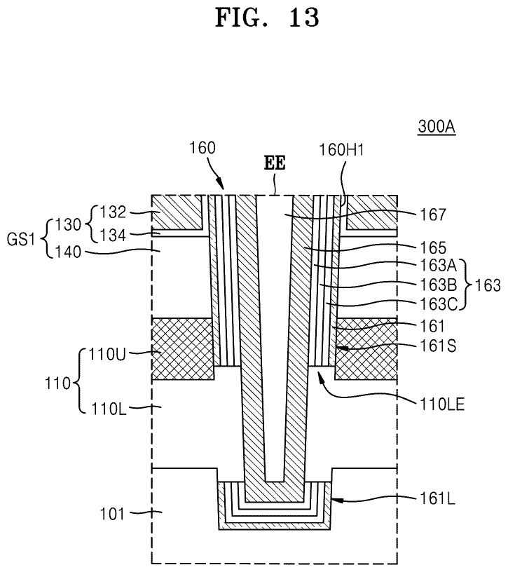

FIG. 13 is a magnified view of part EE of FIG. 12 and illustrates an integrated circuit device 300A including the features of the integrated circuit device 100 described above. The plurality of channel structures 160 may be in contact with the semiconductor substrate 101 and may pass through the base structure 110 including an upper base layer 110U and a lower base layer 110L. At the same level as that of the lower base layer 110L, portions of the ferroelectric layer 161 and the gate insulating layer 163 may be removed, and the channel layer 165 may be in contact with an extension portion 110LE of the lower base layer 110L. A side wall portion 161S and a bottom portion 161L of the ferroelectric layer 161 may be spaced apart from each other with the extension portion 110LE of the lower base layer 110L therebetween, and the bottom portion 161L of the ferroelectric layer 161 may surround a bottom surface of the channel layer 165. Therefore, the channel layer 165 may be electrically connected to the lower base layer 110L instead of being in direct contact with the semiconductor substrate 101.

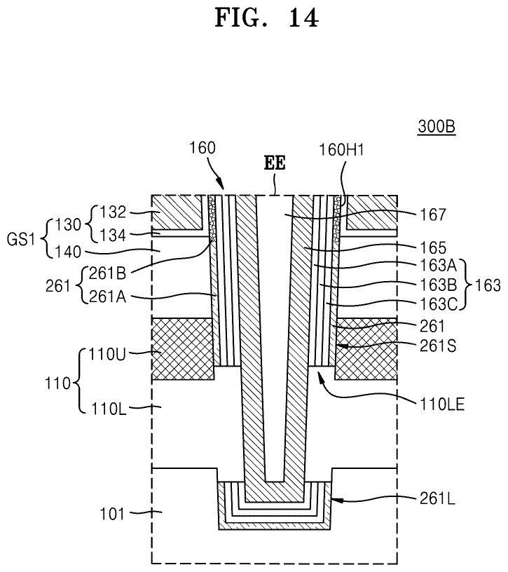

FIG. 14 is a magnified view of part EE of FIG. 12 and illustrates an integrated circuit device 300B including the features of the integrated circuit device 200 described above. The plurality of channel structures 160 may be in contact with the semiconductor substrate 101 and may pass through the base structure 110 including the upper base layer 110U and the lower base layer 110L. At the same level as that of the lower base layer 110L, portions of the dielectric pattern layer 261 and the gate insulating layer 163 may be removed, and the channel layer 165 may be in contact with the extension portion 110LE of the lower base layer 110L. A side wall portion 261S and a bottom portion 261L of the dielectric pattern layer 261 may be spaced apart from each other with the extension portion 110LE of the lower base layer 110L therebetween, and the bottom portion 261L of the dielectric pattern layer 261 may surround the bottom surface of the channel layer 165. Therefore, the channel layer 165 may be electrically connected to the lower base layer 110L instead of being in direct contact with the semiconductor substrate 101.

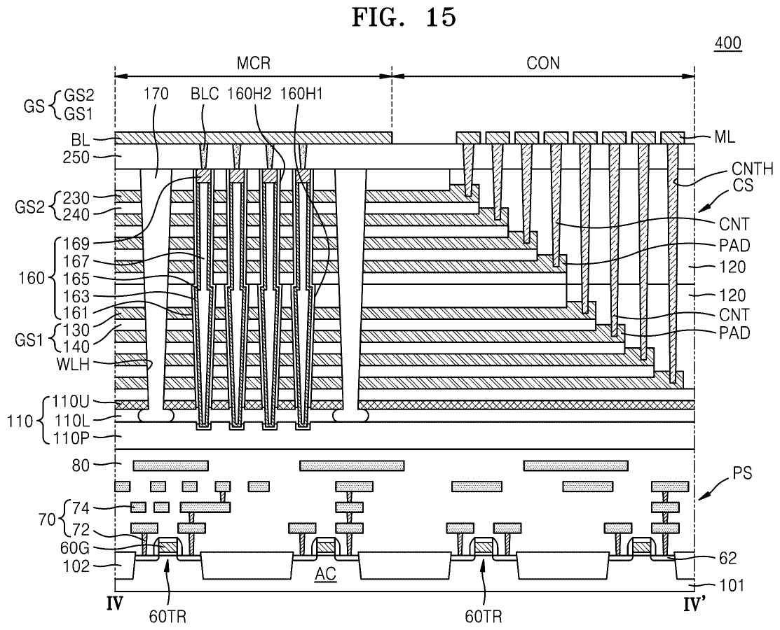

Referring to FIG. 15, the integrated circuit device 400 may include a peripheral circuit structure PS and a cell array structure CS at a vertical level higher than that of the peripheral circuit structure PS.

The integrated circuit device 400 according to the present embodiment may have a cell on periphery (COP) structure in which the cell array structure CS is above the peripheral circuit structure PS. The base structure 110 may be between the peripheral circuit structure PS and the cell array structure CS.

The peripheral circuit structure PS may include a peripheral circuit transistor 60TR and a peripheral circuit wiring 70 on the semiconductor substrate 101. In the semiconductor substrate 101, an active area AC may be defined by a device isolation layer 102, and a plurality of peripheral circuit transistors 60TR may be formed on the active area AC. Each of the plurality of peripheral circuit transistors 60TR may include a peripheral circuit gate 60G and a source/drain region 62 in a portion of the semiconductor substrate 101 at both sides of the peripheral circuit gate 60G.

The peripheral circuit wiring 70 may include a plurality of peripheral circuit contacts 72 and a plurality of peripheral circuit metal layers 74. An interlayer insulating layer 80 covering the plurality of peripheral circuit transistors 60TR and the peripheral circuit wiring 70 may be on the semiconductor substrate 101. The plurality of peripheral circuit metal layers 74 may have a multi-layer structure including a plurality of metal layers at different vertical levels. In an implementation, the plurality of peripheral circuit metal layers 74 may be formed at the same height, or a peripheral circuit metal layer 74 disposed at a certain level (e.g., the top level) may be formed at a greater height than the peripheral circuit metal layers 74 disposed at the other levels.

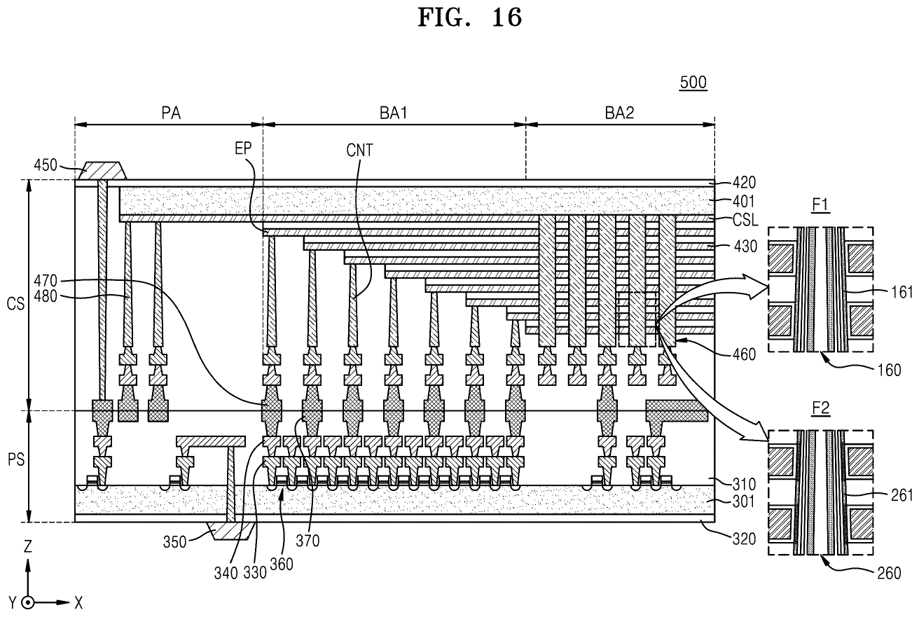

Referring to FIG. 16, the integrated circuit device 500 may include a chip to chip structure.

The integrated circuit device 500 according to the present embodiment may include a chip to chip structure in which an upper chip including the cell array structure CS is manufactured, a lower chip including the peripheral circuit structure PS is manufactured, and then the upper chip and the lower chip are connected to each other by a bonding scheme.

In an implementation, the bonding scheme may indicate a scheme in which bonding pads on the top of the upper chip are in contact with bonding pads on the top of the lower chip. The bonding scheme may include a metal-metal bonding structure, a through silicon via (TSV), a block via stack (BVS), a eutectic bonding structure, a ball grid array (BGA) bonding structure, a plurality of wiring lines, or a combination thereof.

The peripheral circuit structure PS may include a circuit board 301, an interlayer insulating layer 310, a plurality of circuit devices 360, a first metal layer 330 connected to each of the plurality of circuit devices 360, and a second metal layer 340 on the first metal layer 330.

The interlayer insulating layer 310 may be on the circuit board 301 to cover the plurality of circuit devices 360, the first metal layer 330, and the second metal layer 340 and may include an insulating material.

A lower bonding pad 370 may be on the second metal layer 340 in a word line bonding area BA1. In the word line bonding area BA1, the lower bonding pad 370 of the peripheral circuit structure PS may be electrically connected to an upper bonding pad 470 of the cell array structure CS by a bonding scheme.

The cell array structure CS may provide at least one memory block. The cell array structure CS may include a cell substrate 401 and the common source line CSL. Word lines 430 may be stacked on the cell substrate 401 in the third direction (the Z direction).

In a bit line bonding area BA2, a channel structure 460 may pass through the word lines 430, string select lines, and a ground select line in the third direction (the Z direction). In an implementation, the channel structure 460 may be the channel structure 160 including the ferroelectric layer 161. In an implementation, the channel structure 460 may be the channel structure 260 including the dielectric pattern layer 261. The channel structures 160 and 260 may be substantially the same as described above, and thus, a detailed description thereof may be omitted herein.

In the word line bonding area BA1, the word lines 430 may extend in parallel to an upper surface of the cell substrate 401 and may be connected to a plurality of contact plugs CNT. The word lines 430 may be connected to the plurality of contact plugs CNT at ascending end portions EP provided by the word lines 430 extending with different lengths, respectively.

In an external pad bonding area PA, a common source line contact 480 may be arranged. The common source line contact 480 may be formed of a conductive material, such as a metal, a metal compound, or polysilicon, and electrically connected to the common source line CSL.

In an implementation, in the external pad bonding area PA, first and second input-output pads 350 and 450 may be arranged. A lower layer 320 covering a lower surface of the circuit board 301 may be beneath the circuit board 301, and the first input-output pad 350 may be beneath the lower layer 320. An upper layer 420 covering an upper surface of the cell substrate 401 may be on the cell substrate 401, and the second input-output pad 450 may be on the upper layer 420.

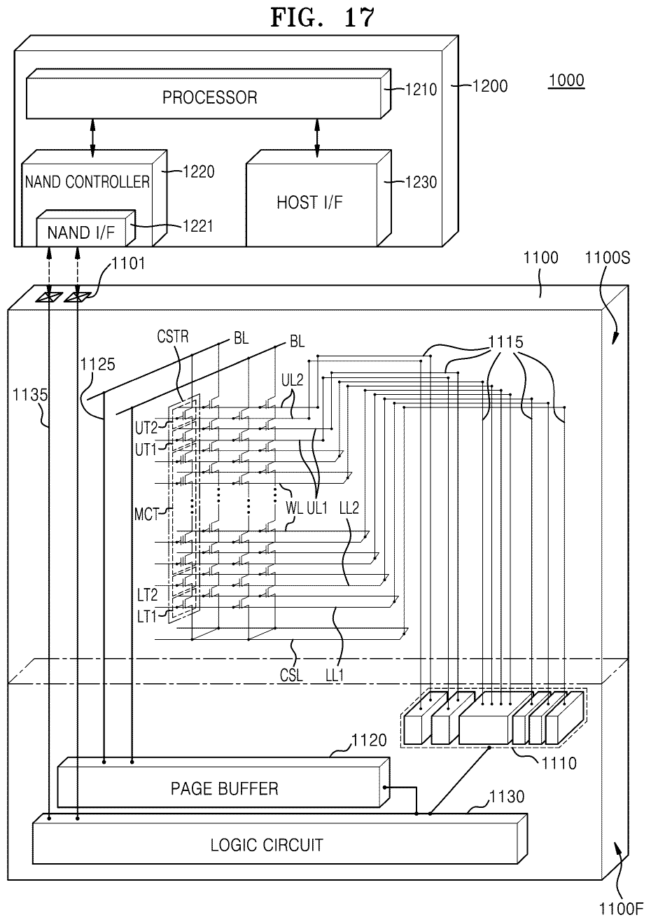

FIG. 17 is a block diagram of an electronic system 1000 including an integrated circuit device 1100, according to an embodiment.

Referring to FIG. 17, the electronic system 1000 according to an embodiment may include the integrated circuit device 1100 and a controller 1200 electrically connected to the integrated circuit device 1100.

The electronic system 1000 may be a storage device including one or more integrated circuit devices 1100, or an electronic device including the storage device. In an implementation, the electronic system 1000 may be a solid state drive (SSD) device, a universal serial bus (USB) device, a computing system, a medical device, or a communication device including at least one integrated circuit device 1100.

The integrated circuit device 1100 may be a nonvolatile vertical memory device. In an implementation, the integrated circuit device 1100 may be a NAND flash memory device including at least one of the integrated circuit devices 100, 200, 300, 400, and 500 described above. The integrated circuit device 1100 may include a first structure 1100F and a second structure 1100S on the first structure 1100F. In an implementation, the first structure 1100F may be beside the second structure 1100S.

The first structure 1100F may be a peripheral circuit structure including a decoder circuit 1110, a page buffer 1120, and a logic circuit 1130. The second structure 1100S may be a memory cell structure including a plurality of bit lines BL, a common source line CSL, a plurality of word lines WL, first and second gate upper lines UL1 and UL2, first and second gate lower lines LL1 and LL2, and a plurality of memory cell strings CSTR between the plurality of bit lines BL and the common source line CSL.

In the second structure 1100S, each of the plurality of memory cell strings CSTR may include lower transistors LT1 and LT2 adjacent to the common source line CSL, upper transistors UT1 and UT2 adjacent to a bit line BL, and a plurality of memory cell transistors MCT between the lower transistors LT1 and LT2 and the upper transistors UT1 and UT2. The number of lower transistors LT1 and LT2 and the number of upper transistors UT1 and UT2 may be variously modified according to embodiments.

In an implementation, the upper transistors UT1 and UT2 may include a string select transistor, and the lower transistors LT1 and LT2 may include a ground select transistor. The first and second gate lower lines LL1 and LL may be gate electrodes of the lower transistors LT1 and LT2, respectively. A word line WL may be a gate electrode of a memory cell transistor MCT, and the first and second gate upper lines UL1 and UL2 may be gate electrodes of the upper transistors UT1 and UT2, respectively.

The common source line CSL, the first and second gate lower lines LL1 and LL2, the plurality of word lines WL, and the first and second gate upper lines UL1 and UL2 may be electrically connected to the decoder circuit 1110 via a plurality of first connection wirings 1115 extending from the inside of the first structure 1100F to the second structure 1100S. The plurality of bit lines BL may be electrically connected to the page buffer 1120 via a plurality of second connection wirings 1125 extending from the inside of the first structure 1100F to the second structure 1100S.

In the first structure 1100F, the decoder circuit 1110 and the page buffer 1120 may execute a control operation for at least one of the plurality of memory cell transistors MCT. The decoder circuit 1110 and the page buffer 1120 may be controlled by the logic circuit 1130.

The integrated circuit device 1100 may communicate with the controller 1200 through input-output pads 1101 electrically connected to the logic circuit 1130. The input-output pads 1101 may be electrically connected to the logic circuit 1130 via input-output connection wirings 1135 extending from the inside of the first structure 1100F to the second structure 1100S.

The controller 1200 may include a processor 1210, a NAND controller 1220, and a host interface 1230. In an implementation, the electronic system 1000 may include a plurality of integrated circuit devices 1100, and in this case, the controller 1200 may control the plurality of integrated circuit devices 1100.

The processor 1210 may control a general operation of the electronic system 1000 including the controller 1200. The processor 1210 may operate according to certain firmware and control the NAND controller 1220 to access the integrated circuit device 1100. The NAND controller 1220 may include a NAND interface 1221 configured to process communication with the integrated circuit device 1100. Through the NAND interface 1221, a control command for controlling the integrated circuit device 1100, data to be written on the plurality of memory cell transistors MCT in the integrated circuit device 1100, data read from the plurality of memory cell transistors MCT in the integrated circuit device 1100, and the like may be transferred. The host interface 1230 may provide a communication function between the electronic system 1000 and an external host. When a control command is received from the external host through the host interface 1230, the processor 1210 may control the integrated circuit device 1100 in response to the control command.

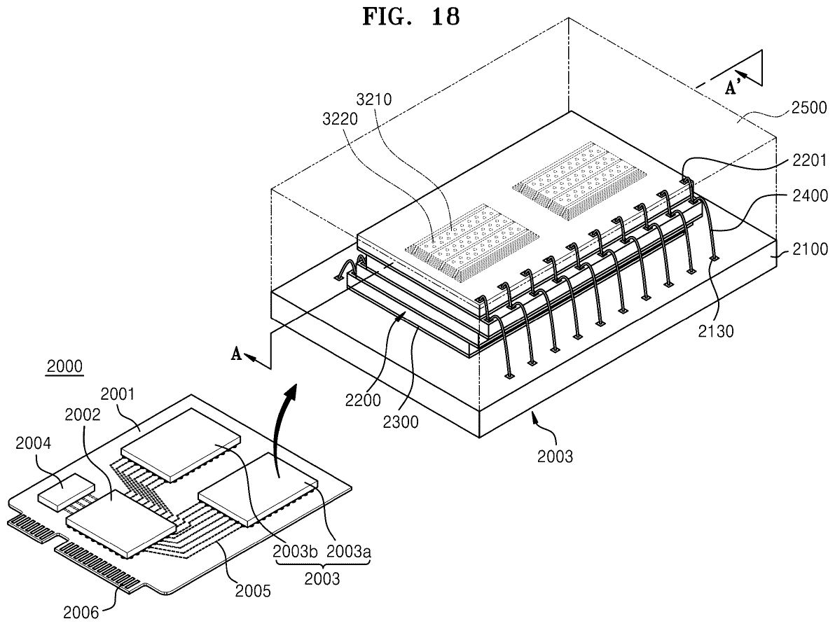

FIG. 18 is a perspective view of an electronic system 2000 including an integrated circuit device, according to an embodiment.

Referring to FIG. 18, the electronic system 2000 according to an embodiment may include a main substrate 2001 and a controller 2002, a semiconductor package 2003, and dynamic random access memory (DRAM) 2004 mounted on the main substrate 2001.

The main substrate 2001 may include a connector 2006 including a plurality of pins coupled to an external host. The number and the arrangement of pins in the connector 2006 may vary according to a communication interface between the electronic system 2000 and the external host. In an implementation, the electronic system 2000 may communicate with the external host according to any one of interfaces, such as a USB interface, a peripheral component interconnect express (PCI-Express) interface, a serial advanced technology attachment (SATA) interface, or an M-Phy interface for a universal flash storage (UFS). In an implementation, the electronic system 2000 may operate by power received from the external host through the connector 2006. The electronic system 2000 may further include a power management integrated circuit (PMIC) configured to distribute the power received from the external host to the controller 2002 and the semiconductor package 2003. The semiconductor package 2003 and the DRAM 2004 may be connected to the controller 2002 through a plurality of wiring patterns 2005 formed on the main substrate 2001.

The controller 2002 may write or read data on or from the semiconductor package 2003 and improve an operating speed of the electronic system 2000.

The DRAM 2004 may be a buffer memory configured to mitigate a speed difference between the semiconductor package 2003, which is a data storage space, and the external host. The DRAM 2004 included in the electronic system 2000 may operate as a kind of cache memory and provide a space in which data is temporarily stored in a control operation on the semiconductor package 2003. When the DRAM 2004 is included in the electronic system 2000, the controller 2002 may further include a DRAM controller configured to control the DRAM 2004 in addition to a NAND controller configured to control the semiconductor package 2003.

The semiconductor package 2003 may include first and second semiconductor packages 2003a and 2003b separated from each other. Each of the first and second semiconductor packages 2003a and 2003b may include a plurality of semiconductor chips 2200. Each of the first and second semiconductor packages 2003a and 2003b may include a package substrate 2100, the plurality of semiconductor chips 2200 on the package substrate 2100, an adhesive layer 2300 beneath each of the plurality of semiconductor chips 2200, a plurality of connection structures 2400 electrically connecting the plurality of semiconductor chips 2200 to the package substrate 2100, and a molding layer 2500 covering the plurality of semiconductor chips 2200 and the plurality of connection structures 2400 on the package substrate 2100.

The package substrate 2100 may be a printed circuit board including a plurality of package upper pads 2130. Each of the plurality of semiconductor chips 2200 may include input-output pads 2201. The input-output pads 2201 may correspond to the input-output pads 1101 of FIG. 17. Each of the plurality of semiconductor chips 2200 may include a plurality of gate stacks 3210 and a plurality of channel structures 3220. Each of the plurality of semiconductor chips 2200 may include at least one of the integrated circuit devices 100, 200, 300, 400, and 500 described above.

In an implementation, the plurality of connection structures 2400 may be bonding wires electrically connecting the input-output pads 2201 to the plurality of package upper pads 2130. Therefore, in the first and second semiconductor packages 2003a and 2003b, the plurality of semiconductor chips 2200 may be electrically connected to each other by a bonding wire scheme and electrically connected to the plurality of package upper pads 2130 of the package substrate 2100. In an implementation, in the first and second semiconductor packages 2003a and 2003b, the plurality of semiconductor chips 2200 may be electrically connected to each other through a connection structure including TSVs instead of the plurality of connection structures 2400 of the bonding wire scheme.

In an implementation, the controller 2002 and the plurality of semiconductor chips 2200 may be included in one package. In an implementation, the controller 2002 and the plurality of semiconductor chips 2200 may be mounted on a separate interposer substrate other than the main substrate 2001, and the controller 2002 may be connected to the plurality of semiconductor chips 2200 through wirings formed on the interposer substrate.

One or more embodiments may provide an integrated circuit device having a nonvolatile vertical memory device.

One or more embodiments may provide an integrated circuit device with an improved retention characteristic and improved product reliability by arranging a ferroelectric layer on the periphery of a gate insulating layer in a channel structure and using remanent polarization of the ferroelectric layer to help prevent a loss of electrons or holes.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An integrated circuit device, comprising:
a semiconductor substrate;
a plurality of conductive lines extending on the semiconductor substrate in a horizontal direction and overlapping each other in a vertical direction;
a plurality of insulating layers between pairs of conductive lines of the plurality of conductive lines and extending in the horizontal direction; and
a channel structure passing through the plurality of conductive lines and the plurality of insulating layers,
wherein the channel structure includes:
a core insulating layer,
a channel layer on a side wall and a bottom surface of the core insulating layer,
a gate insulating layer on an outer wall of the channel layer, and
a ferroelectric layer on an outer wall of the gate insulating layer.

2. The integrated circuit device as claimed in claim 1, further comprising an insulating liner conformally surrounding an upper surface, a lower surface, and a side surface of each of the plurality of conductive lines, wherein the insulating liner includes a metal oxide layer and is in contact with the ferroelectric layer of the channel structure.

3. The integrated circuit device as claimed in claim 2, wherein:
the ferroelectric layer includes hafnium zirconium oxide (HfZrO), and
a ratio of hafnium (Hf) to zirconium (Zr) in the HfZrO is about 1:1.

4. The integrated circuit device as claimed in claim 3, wherein a thickness of the ferroelectric layer in the horizontal direction is about 30 Å to about 100 Å.

5. The integrated circuit device as claimed in claim 2, wherein:
the metal oxide layer is between each of the plurality of conductive lines and the ferroelectric layer, and
the metal oxide layer includes aluminum oxide (Al₂O₃).

6. The integrated circuit device as claimed in claim 2, wherein the gate insulating layer includes a tunneling dielectric layer, a charge storage layer, and a blocking dielectric layer sequentially on the outer wall of the channel layer.

7. The integrated circuit device as claimed in claim 6, wherein movement of electrons or holes stored in the charge storage layer is suppressed by remanent polarization of the ferroelectric layer.

8. The integrated circuit device as claimed in claim 6, wherein the ferroelectric layer is between the metal oxide layer and the blocking dielectric layer.

9. The integrated circuit device as claimed in claim 6, wherein:
the tunneling dielectric layer includes silicon oxide (SiO),
the charge storage layer includes silicon nitride (SiN), and
the blocking dielectric layer includes SiO.

10. The integrated circuit device as claimed in claim 9, wherein a thickness of the SiO included in the blocking dielectric layer is about 20 Å to about 50 Å.

11. An integrated circuit device, comprising:
a semiconductor substrate;
a plurality of conductive lines extending on the semiconductor substrate in a horizontal direction and overlapping each other in a vertical direction;
a plurality of insulating layers between pairs of conductive lines of the plurality of conductive lines and extending in the horizontal direction; and
a channel structure passing through the plurality of conductive lines and the plurality of insulating layers,
wherein the channel structure includes:
a core insulating layer,
a channel layer on a side wall and a bottom surface of the core insulating layer,
a gate insulating layer on an outer wall of the channel layer, and
a high-k pattern and a ferroelectric pattern alternating in the vertical direction on an outer wall of the gate insulating layer.

12. The integrated circuit device as claimed in claim 11, further comprising an insulating liner conformally surrounding an upper surface, a lower surface, and a side surface of each of the plurality of conductive lines, wherein the insulating liner includes a metal oxide layer and is in contact with the ferroelectric pattern of the channel structure.

13. The integrated circuit device as claimed in claim 12, wherein:
the metal oxide layer includes aluminum oxide (Al₂O₃),
the high-k pattern includes hafnium oxide (HfO), and
the ferroelectric pattern includes hafnium aluminum oxide (HfAlO).

14. The integrated circuit device as claimed in claim 13, wherein aluminum (Al) included in the ferroelectric pattern spreads in a process of crystallizing the metal oxide layer, and HfAlO exists in a form of nanocrystals.

15. The integrated circuit device as claimed in claim 14, wherein the process of crystallizing the metal oxide layer is performed by a spike annealing process.

16. The integrated circuit device as claimed in claim 14, wherein an amount of Al in HfAlO included in the nanocrystals is about 4.5%.

17. The integrated circuit device as claimed in claim 11, wherein:
each conductive line of the plurality of conductive lines faces the ferroelectric pattern, and
each insulating layer of the plurality of insulating layers faces the high-k pattern.

18. The integrated circuit device as claimed in claim 17, wherein a length of each insulating layer of the plurality of insulating layers in the vertical direction is greater than or equal to a length of the facing high-k pattern in the vertical direction.

19. An electronic system, comprising:
a main substrate;
an integrated circuit device on the main substrate; and
a controller electrically connected to the integrated circuit device on the main substrate,
wherein:
the integrated circuit device includes:
a semiconductor substrate;
a plurality of conductive lines extending on the semiconductor substrate in a horizontal direction and overlapping each other in a vertical direction;
a plurality of insulating layers between pairs of conductive lines of the plurality of conductive lines and extending in the horizontal direction; and
a channel structure passing through the plurality of conductive lines and the plurality of insulating layers, and
the channel structure includes:
a core insulating layer,
a channel layer on a side wall and a bottom surface of the core insulating layer,
a gate insulating layer on an outer wall of the channel layer, and
a ferroelectric layer on at least a portion of an outer wall of the gate insulating layer.

20. The electronic system as claimed in claim 19, wherein:
the main substrate further includes wiring patterns electrically connecting the integrated circuit device to the controller,
the integrated circuit device further includes an insulating liner conformally surrounding an upper surface, a lower surface, and a side surface of each of the plurality of conductive lines, and
the insulating liner includes a metal oxide layer and is in contact with the ferroelectric layer of the channel structure.
